(19) United States
(12) Patent Application Publication
(10) Pub. No.: US 2025/0258237 A1
(43) Pub. Date: Aug. 14, 2025

(54) CIRCUIT AND METHOD FOR MONITORING THE CHARGE LEVEL OF A BATTERY

(71) Applicant: STMicroelectronics International N.V., Geneva (CH)

(72) Inventor: Andrei TUDOSE, Chateauneuf (FR)

(21) Appl. No.: 19/056,204

(22) Filed: Feb. 18, 2025

(30) Foreign Application Priority Data
Feb. 29, 2024 (FR) FR2402057

(51) Int. Cl. G01R 31/3835; G01R 31/371; G01R 31/378; H01M 10/052; H01M 10/48

(52) U.S. Cl. CPC G01R 31/3835; G01R 31/371; G01R 31/378; H01M 10/052; H01M 10/48

(57) ABSTRACT

An electronic device comprising a rechargeable battery and a circuit and a method for monitoring the charge level of the battery is provided. An example device comprises: a rechargeable battery; a first circuit comprising a processor, and a voltage comparator configured to compare the voltage of the rechargeable battery with a limiting voltage; and a second circuit, coupled to the first circuit, comprising a memory of non-volatile type and configured to initialize the processor of the first circuit if the voltage of the rechargeable battery is higher than the limiting voltage.

### CROSS REFERENCE TO RELATED APPLICATIONS

This application claims the priority benefit of French patent application number FR2402057, filed on Feb. 29, 2024, entitled “Circuit et procédé de surveillance du niveau de charge d′une batterie”, which is hereby incorporated by reference to the maximum extent allowable by law.

### TECHNICAL FIELD

The present disclosure generally concerns electronic devices comprising a rechargeable battery and more particularly a circuit and a method for monitoring the charge level of a battery.

### BACKGROUND

An electronic device can be powered by a rechargeable battery. However, if the battery charge level becomes too low, some of the circuits of the device may no longer operate properly, and it may be preferable to perform a resetting of the device. To avoid such a situation, the battery charge level can be estimated before starting up all or part of the device, and during the operation of the device.

The tracking of the charge level of a battery generally comprises a measurement of the voltage across the rechargeable battery, by means of an analog-to-digital converter (ADC), and the comparison of the measured voltage with a threshold. However, existing solutions are not adequate in all applications, particularly when it is desirable to have a relatively low cost and chip surface area.

### BRIEF SUMMARY

Embodiments of the present application are capable of overcoming all or part of the problems existing in prior art.

According to a first aspect, there is provided a device comprising:
a rechargeable battery;
a first circuit comprising a processor and a voltage comparator configured to compare the voltage of the rechargeable battery with a limiting voltage; and
a second circuit, coupled to the first circuit, comprising a memory of non-volatile type and configured to initialize the processor of the first circuit if the voltage of the rechargeable battery is higher than the limiting voltage.

According to an embodiment, the memory of the second circuit is a flash-type memory.

According to an embodiment, the device further comprises a voltage regulator configured to power the first and second circuits with voltage.

According to an embodiment, the first circuit comprises a connection terminal coupled to a connection terminal of the second circuit, a signal present at the connection terminal of the first circuit being either in a first state or in a second state, according to the charge level of the rechargeable battery.

According to an embodiment, the signal present at the connection terminal of the first circuit is in the second state if the battery voltage is lower than the limiting voltage.

According to an embodiment, the second circuit is configured to reset the processor and/or to generate an alert signal if the signal present at the connection terminal of the first circuit is in the second state.

According to an embodiment, the voltage of the connection terminal of the first circuit in the first state is higher than the voltage of the connection terminal of the first circuit in the second state.

According to an embodiment, the first circuit further comprises an analog-to-digital converter configured to generate a digital value representative of the voltage of the rechargeable battery.

According to an embodiment, the rechargeable battery is a lithium battery.

According to another aspect, there is provided a method comprising:
the comparison, by a first circuit, of a voltage of a rechargeable battery with a limiting voltage; and
the initialization of a processor of the first circuit, by a second circuit comprising a memory of non-volatile type, if the voltage of the rechargeable battery is higher than the limiting voltage.

According to an embodiment, the method also comprises, prior to the running of a program by the processor, the comparison of the rechargeable battery voltage with a threshold voltage, and the running of the program only if the voltage of the rechargeable battery is higher than the threshold voltage.

According to an embodiment, the method also comprises the resetting of the processor and/or the sending of an alert signal by the second circuit if the voltage of the rechargeable battery is lower than the limiting voltage.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 schematically shows in the form of blocks a device comprising a rechargeable battery according to an embodiment;

FIG. 2 is a flowchart representing operations of a method of monitoring the voltage of a rechargeable battery, at the starting of the device of FIG. 1, according to an embodiment of the present application;

FIG. 3 schematically shows in the form of blocks the device of FIG. 1 in further detail;

FIG. 4 is a flowchart showing operations of a method of monitoring the voltage of a rechargeable battery according to another embodiment of the present application;

FIG. 5 is a graph showing an example of the variation of certain voltages of the device of FIG. 3, according to an embodiment; and

FIG. 6 is a graph showing another example of the variation of certain voltages of the device of FIG. 3, according to an embodiment.

### DETAILED DESCRIPTION

Like features have been designated by like references in the various figures. In particular, the structural and/or functional features that are common among the various embodiments may have the same references and may dispose identical structural, dimensional and material properties.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

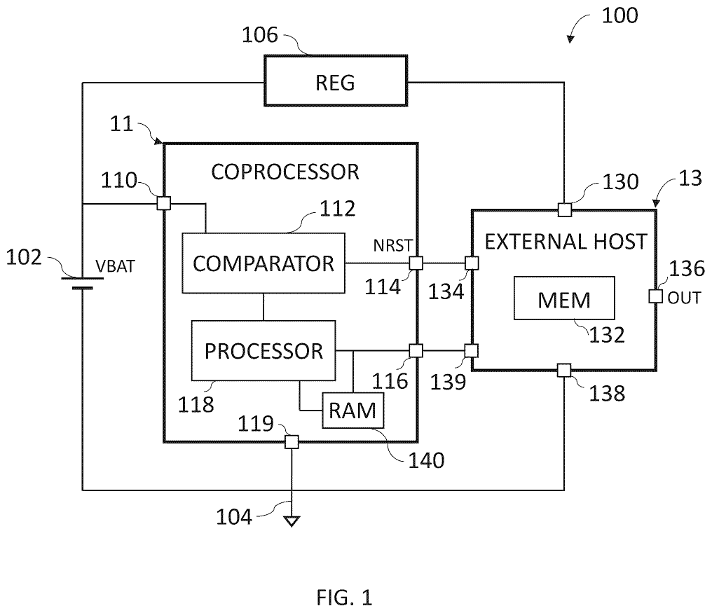

FIG. 1 schematically shows in the form of blocks a device 100 comprising a rechargeable battery 102 according to an embodiment.

Device 100 comprises a first circuit 11 (“COPROCESSOR”) and a second circuit 13 (“EXTERNAL HOST”). In an example, circuit 13 is a host of device 100 comprising a first processor (not shown in FIG. 1), and circuit 11 is a coprocessor comprising a processor 118 (“PROCESSOR”). Circuit 11 is for example implemented by a first integrated circuit, and circuit 13 is for example implemented by a second integrated circuit external to the first integrated circuit.

Rechargeable battery 102, for example a lithium battery, has a voltage VBAT between its terminals which varies according to its charge level. Battery 102 is coupled to a ground rail 104 of device 100 and powers circuit 11 with a voltage via a connection terminal 110 of first circuit 11. Battery 102 powers circuit 13 with a voltage via a voltage regulator 106 (“REG”). Voltage regulator 106 for example applies a gain to voltage VBAT so that the output voltage of voltage regulator 106 is within a voltage range compatible with the digital circuits of circuit 13. Voltage VBAT is for example in the range from 0 V to 6 V and for example from 0 V to 4.5 V according to the charge level of the battery. The output voltage of the voltage regulator is, for example, in the range from 0 V to 4 V and, for example, from 0 V to 2 V, according to the set point voltage of voltage regulator 106 and/or to the charge level of battery 102. The output voltage of the regulator is coupled to a connection terminal 130 of circuit 13.

Circuit 13 is powered with a power supply voltage lower than that which powers circuit 11. Thus, if rechargeable battery 102 is no longer sufficiently charged and voltage VBAT becomes lower than the power supply voltage of circuit 11, circuit 13 remains operational and, for example, emits an alert signal to notify a user that a charge of the battery is required.

Circuit 11 for example comprises a connection terminal 119 coupled to the ground rail 104 of device 100.

Circuit 11 comprises a comparator 112 (“COMPARATOR”) to which is coupled the voltage VBAT of terminal 110 and processor 118. Comparator 112 is configured to compare voltage VBAT with a limiting voltage VLIM (not shown in FIG. 1). Limiting voltage VLIM corresponds, for example, to the minimum operating voltage of at least one circuit of device 100, for example of processor 118. Voltage VLIM is, for example, in the range from 1 to 3 V and, for example, from 2.6 to 2.8 V.

According to an embodiment, the output voltage of comparator 112 is in a first state, for example a high-voltage state, if VBAT is higher than VLIM, and in a second state, for example a low-voltage state, if VBAT is lower than VLIM.

According to another embodiment, voltage VBAT is compared with limiting voltage VLIM and with a second limiting voltage, the second limiting voltage being higher than voltage VLIM. For example, limiting voltage VLIM is equal to 2.7 V and the second limiting voltage is equal to 2.73 V. The output voltage of comparator 112 is in the first state if VBAT is higher than the second limiting voltage, and the output voltage of comparator 112 is in the second state if VBAT is lower than voltage VLIM. The output voltage of comparator 112 remains unchanged if VBAT is between the two limiting voltages. This embodiment involves a hysteresis to prevent an oscillation of the output signal of comparator 112 when VBAT is close to the trip point of the comparator.

The output voltage of comparator 112 is coupled to a connection terminal 114 of circuit 11.

The voltage at terminal 114, noted “NRST”, is indicative of the state of charge of battery 102.

When voltage VBAT becomes lower than limiting voltage VLIM, voltage NRST enters the second state and circuit 11 transitions, for example, to a reset state.

In certain embodiments, first circuit 11 is configured to maintain the second state even if the battery voltage VBAT falls below a minimum level for the correct operation of circuit 11. In addition, first circuit 11 is configured, for example, to maintain the first state as long as the battery voltage VBAT remains above the minimum level for the correct operation of circuit 11, and otherwise to switch to the second state. Indeed, the choice of the low-voltage state for the second state and of powering the comparator 112 with voltage VBAT ensures that, if voltage VBAT falls below the threshold of limiting voltage VLIM, then voltage NRST will naturally decrease towards the low-voltage state, indicative of a low battery level 102.

The second circuit 13 includes a non-volatile memory 132 (MEM), used at the starting up of device 100.

Circuit 13 comprises a connection terminal 134 coupled to the connection terminal 114 of circuit 11. Circuit 13 is for example configured to estimate the charge level of battery 102 by reading the voltage NRST at terminal 134. According to an embodiment, if NRST is in the second state, then the battery is not sufficiently charged and circuit 13 emits an alert signal, for example addressed to the user of device 100, via a connection terminal 136 (“OUT”), and a signaling device such as a LED or a sound signal generator.

Second circuit 13 for example comprises a connection terminal 138 coupled to the ground rail 104 of device 100 and for example comprises a connection terminal 139 coupled to a connection terminal 116 of first circuit 11.

Connection terminal 116 is coupled to the processor 118 of circuit 11 so that circuit 13 can communicate with processor 118. The communication is carried out according to SPI (Serial Peripheral Interface) or SDIO (Secure Digital Input Output) protocols, for example, via a data bus. For example, an SPI interface between connection terminal 139 and connection terminal 116 is equipped with a MOSI (Master Output, Slave Input) data line for transmitting data from circuit 13 to circuit 11, and a MISO (Master Input, Slave Output) data line for transmitting data from circuit 11 to circuit 13. In another example, an SDIO interface between connection terminal 139 and connection terminal 116 is also equipped with one communication line in each direction or with a plurality of, for example 4, communication lines in each of the directions, multiplying by the same amount the communication speed between circuits.

According to an embodiment, circuit 11 comprises no non-volatile memory and for example comprises a volatile memory, for example, of random access memory (RAM) type 140. The initialization of processor 118 is performed by circuit 13 and for example by the loading of a binary code into RAM 140. For example, a binary code recorded in the memory 132 of circuit 13 is loaded into RAM 140 at the starting up of processor 118. Processor 118 is for example configured to read the binary code and to execute it.

According to an embodiment, processor 118 is coupled to the output of comparator 112 to receive the result of the comparison between the voltage of battery 102 VBAT and voltage VLIM.

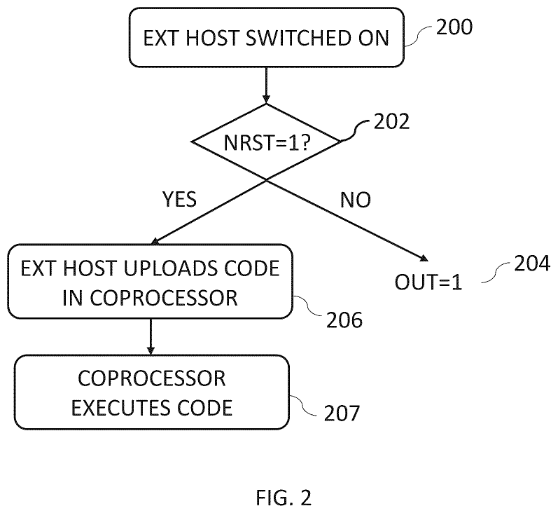

FIG. 2 is a flowchart showing operations of a method of monitoring the voltage of a rechargeable battery, for example the battery 102 of FIG. 1, at the starting up of the device 100 of FIG. 1, according to an embodiment of the present application. This method is for example carried out by the comparator 112 and the processor 118 of circuit 11 and by circuit 13.

In a step 200 of the method (“EXT HOST SWITCHED ON”), circuit 13 is for example started up. For example, the starting up is triggered manually by the user or automatically, for example by a low-power timer integrated to circuit 13. At the starting up of circuit 13, at least one binary code is executed by this circuit. The binary code is stored, for example, in the non-volatile memory 132 of FIG. 1.

In a step 202 (“NRST=1?”) following the starting up of circuit 13, circuit 13 is configured, for example, to check the logic state of the terminal 134 of FIG. 1. If terminal 132 is in the second state (“NO” output of block 202), this means that voltage VBAT is lower than VLIM and that the battery is no longer sufficiently charged for a minimal operation of device 100. A signal is for example transmitted to the user (block 204, “OUT=1”), for example a LED is turned on, to indicate that the battery is to be charged, and processor 118 remains off.

If terminal 134 is in the first state (output “YES” of block 202), this means that voltage VBAT is higher than VLIM and that the battery is sufficiently charged to start processor 118.

In a step 206 (“EXT HOST UPLOADS CODE IN PROCESSOR”), circuit 13 for example uploads a binary code stored in non-volatile memory 132 into the volatile memory 140 of the circuit 11 of FIG. 1. The code is for example transmitted via an interface, for example a data bus, between connection terminals 139 and 116 and for example according to an SDIO or SPI protocol. The transmitted code for example enables to initialize the processor 118 of circuit 11, which for example comprises no non-volatile memory.

In a step 207 (“COPROCESSOR EXECUTES CODE”), the processor 118 of circuit 11 executes the binary code, for example following a code verification step.

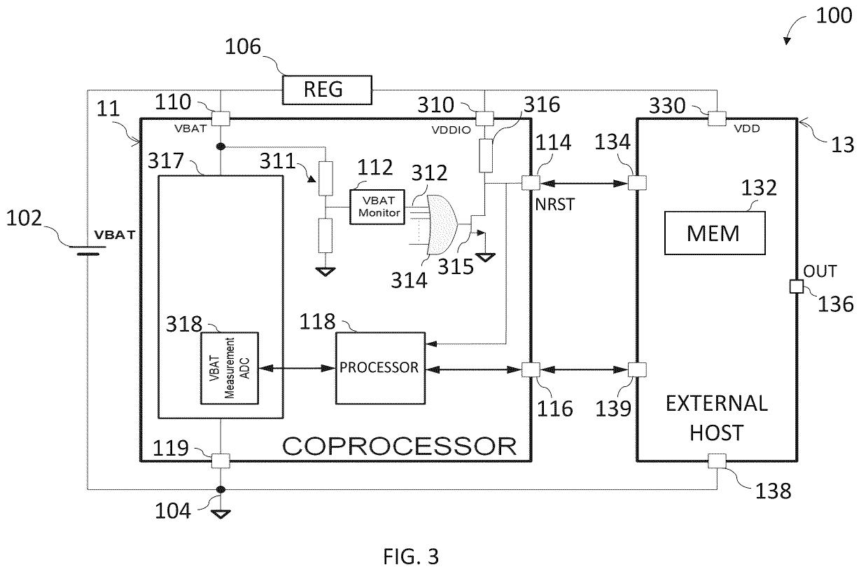

FIG. 3 schematically shows in the form of blocks a diagram of the device 100 of FIG. 1 in further detail.

Certain elements of FIG. 3 are identical to elements of FIG. 1. They are shown with the same reference numeral and will not be detailed again.

According to an embodiment, the rechargeable battery 102 is connected between the ground rail 104 of device 100 on the one hand and the connection terminal 110 of circuit 11, as well as to voltage regulator 106 on the other hand.

Voltage regulator 106 for example applies a gain to voltage VBAT so that the output voltage of the regulator is within a voltage range compatible with the digital circuits of device 100. The output voltage of the regulator is coupled to a connection terminal 310 (“VDDIO”) of circuit 11 and to a connection terminal 330 (“VDD”) of circuit 13.

According to an embodiment, circuit 13 is configured to be powered with a power supply voltage lower than VLIM, for example in the range from 1.6 V to 2 V, for example 1.8 V±10%. The output voltage of the voltage regulator then corresponds to the power supply voltage of circuit 13.

According to another embodiment, circuit 13 is configured to be powered with a power supply voltage ALIM higher than VLIM, for example in the range from 2.8 V to 3.2 V. When VBAT is higher than ALIM, voltage regulator 106 is configured to generate voltage ALIM. When VBAT is lower than ALIM, voltage regulator 106 is configured to generate a voltage which follows the variation of voltage VBAT.

The voltage VBAT at the terminal 110 of circuit 11 is for example divided by a voltage dividing bridge 311, for example formed of two resistors coupled in series between terminal 110 and ground rail 104, an intermediate node between the resistors delivering the divided voltage. The divided voltage is compared with limiting voltage VLIM by comparator 112 (“VBAT Monitor”). The output voltage of comparator 112 is, for example, in the first state if VBAT is lower than VLIM, and for example in the second state if VBAT is higher than VLIM.

The output 312 of comparator 112 is for example coupled to an input of an OR logic gate 314. Logic gate 314 for example comprises other inputs coupled to fault detection circuits (not illustrated in FIG. 3) present in circuit 11 and which are in the first state in the case of a fault detection.

The output of logic gate 314 will be in the first state if at least one of its inputs is in the first state, and in the second state if all the inputs of logic gate 314 are in the second state. According to an embodiment, the output of logic gate 314 is in the first state in the event of a fault detected in circuit 11 or when battery 102 is no longer sufficiently charged.

The output of logic gate 314 is, for example, connected to the gate of a transistor 315, which is, for example, an n-channel MOS transistor (nMOS). The source of transistor 315 is coupled to ground rail 104, and the drain of transistor 315 is coupled to connection terminal 114 and to a first electrode of resistor 316. The state of the voltage NRST at terminal 114 is the opposite of the state of the voltage at the gate of transistor 315. The second electrode of resistor 316 is coupled to connection terminal 310. Electrode 316 is a pull-up resistor and enables to decrease a conduction between connection terminal 310 and ground rail 104 when transistor 315 is activated.

Voltage NRST is indicative of the state of charge of battery 102.

The arrangement of transistor 315 enables to maintain the second state at terminal 114 even if battery voltage VBAT falls below a minimum level for the correct operation of circuit 11. Further, transistor 315 enables to maintain the first state at terminal 114 as long as battery voltage VBAT remains above the minimum level for the correct operation of circuit 11, and otherwise to switch to the second state. The choice of the low-voltage state for the second state and of powering terminal 114 with voltage VBAT ensures that, if voltage VBAT falls below the threshold of limiting voltage VLIM, then voltage NRST will naturally decrease towards the low-voltage state, indicative of a low level of battery 102. If the processor 118 of circuit 11 is off, the other inputs of logic gate 314 are for example fixed at the low-voltage level, and only the input corresponding to the voltage level 312 of battery 102 can vary. Voltage NRST 114 thus remains indicative of the voltage level of battery VBAT before turning on the processor 118 of circuit 11.

The drain of transistor 315 is for example also coupled to the processor 118 (“PROCESSOR”) of first circuit 11. Processor 118 for example takes into account a fault detected in device 100 and the battery charge level via the level of the voltage NRST present at the drain of transistor 315.

The processor 118 of circuit 11 is, for example, coupled to a module 317 of circuit 11. Module 317 is for example coupled to a connection terminal 119 of circuit 11 which is for example coupled to the ground rail 104 of device 100. Module 317 is for example coupled to terminal 110 to be powered with voltage VBAT and is for example configured to execute functions of device 100, for example the establishing of a wireless communication with an external device, not shown in FIG. 3. Module 317 for example comprises a voltage measurement circuit 318 (“VBAT Measurement ADC”) comprising an analog-to-digital converter.

According to an embodiment, when VBAT is higher than VLIM, circuit 11 measures the value of voltage VBAT via voltage measurement circuit 318 and transmits the value of VBAT to circuit 13 via connection terminals 116 and 139. Circuit 11 is, for example, configured to be able to operate in different operating states, for example a state consuming less energy if voltage VBAT is lower than a fixed voltage, higher than limiting voltage VLIM, for example 3 V. According to the value of VBAT, circuit 13 is for example configured to control the operating state of circuit 11.

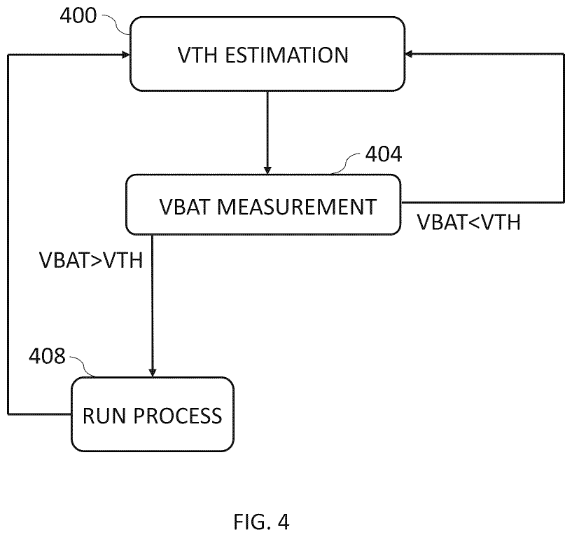

In certain embodiments, before a program is run by the processor 118 of circuit 11, the voltage VBAT of rechargeable battery 102 is compared with a threshold voltage VTH to verify that voltage VBAT is above this threshold. Threshold voltage VTH corresponds, for example, to a minimum voltage for the correct running of the program. The optional taking into account of threshold voltage VTH will now be described in relation with FIG. 4.

FIG. 4 is a flowchart showing operations of a method of monitoring the voltage of a battery rechargeable by circuit 13, for example the battery 102 of FIG. 1 or of FIG. 3.

Threshold voltage VTH is associated with a given program which will be for example run by processor 118. If processor 118 is configured to run a plurality of programs, each program for example has an associated threshold voltage, which may vary with respect to one another according to the power consumption required by the running of the program.

In a step 400 (“VTH ESTIMATION”), before the running of a program, the threshold voltage VTH associated with the program is for example estimated. Threshold voltage VTH depends on the power consumption required by the running of the program, so that the voltage of battery 102 VBAT remains above limiting voltage VLIM at the end of the running of the program. The estimation of threshold voltage VTH for example takes into account the equivalent resistance of battery 102 and the electrical current used during the running of the program, to estimate the charge which will be consumed during the running. For example, if rechargeable battery 102 has an equivalent resistance of 1 ohm and the program requires 200 mA, then the running of the program will consume 200 mV and VTH will, for example, be selected equal to the sum of VLIM and 200 mV so that the battery voltage remains above VLIM after the running of the program. According to an embodiment, instead of estimating the threshold voltage VTH associated with the program, the value of threshold voltage VTH is, for example, recorded in non-volatile memory 132 during the manufacturing of device 100 or later on by a user.

In a step 404 (“VBAT MEASUREMENT”), the voltage VBAT of battery 102 is measured by voltage measurement circuit 318 and is for example transmitted to circuit 13 via connection terminals 116 and 139. Circuit 13 compares value VBAT with threshold voltage VTH.

If voltage VBAT is higher than threshold voltage VTH (output “VBAT>VTH” of block 404), it is considered that the battery is sufficiently charged for the running of the program, and circuit 13 is for example configured to transmit the order to processor 118 to run the program (block 408, “RUN PROCESS”). To run a new program, the process resumes at step 400, where a new threshold voltage is estimated.

If voltage VBAT is lower than voltage VTH (output “VBAT<VTH” of block 404), it is considered that battery 102 is not sufficiently charged for the running of the program and an alert signal is for example emitted by circuit 13. According to value VBAT, a second, less energy-consuming program may for example be run with the remaining charge level of the battery. Circuit 13 is for example configured so that the method returns to block 400 and that a new threshold voltage associated with the second program is estimated.

In parallel with the method of monitoring the voltage of battery 102 illustrated in FIG. 4, voltage VBAT is compared with voltage VLIM by the voltage comparator 112 of circuit 11, as previously described in relation with FIGS. 1 to 3. If voltage VBAT becomes lower than voltage VLIM, voltage NRST switches from the first state to the second state, and circuit 13 for example emits an alert signal to notify a user that a battery charge is required.

Although in the example shown in FIG. 4 there is a step 400 of estimation of threshold voltage VTH, in other embodiments this step may be replaced with a step of generation of threshold voltage VTH based on a control signal or on a precalculated value stored in the memory.

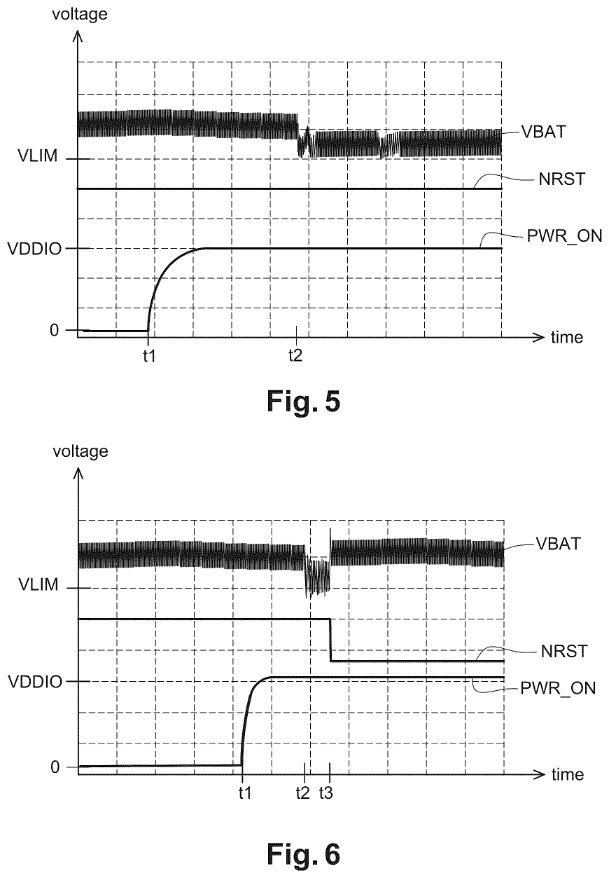

FIG. 5 is a graph showing an example of the variation of voltage VBAT, of voltage NRST, and of a voltage PWR_ON of the device 100 of FIGS. 1 and 3, according to an embodiment.

Voltage PWR_ON is a voltage representative of the power supply voltage of processor 118 or of the output voltage of voltage regulator 106. For example, PWR_ON=0 V when circuit 11 is off and PWR_ON=VDDIO when circuit 11 is on. In the example of FIG. 5, circuit 11 is switched on at time t1 and voltage PWR_ON transits from 0 V to VDDIO.

The voltage VBAT of battery 102 is, in the example of FIG. 5, higher than limiting voltage VLIM. Voltage VBAT decreases, for example, according to the activity of circuit 11. For example, a program is run by circuit 11 at time t2, which causes a current consumption by device 100 and a decrease in voltage VBAT.

In the example of FIG. 5, voltage VBAT remains higher than VLIM. Thus, voltage NRST remains in the same state, for example the high state, and the processor 118 of circuit 11 keeps on running the program.

FIG. 6 is a graph showing another example of the variation of the voltages VBAT, NRST, and PWR_ON of the device 100 of FIGS. 1 and 3, according to an embodiment.

As in the example of FIG. 5, circuit 11 is switched on at time t1 and voltage PWR_ON transits from 0 V to VDDIO.

In the example of FIG. 6, a program is for example run at time t2, a current is consumed by device 100 and voltage VBAT falls below limiting voltage VLIM. Voltage NRST transits from the first state to the second state at time t3, where t3 is offset from time t2 by a delay introduced by circuit 11. In the example of FIG. 6, voltage NRST transits from the high state to the low state. Circuit 11 then enters the reset state, its clock signal is for example stopped until voltage VBAT is sufficiently high for voltage NRST to return from the second state to the first state. The processor 118 of circuit 11 stops the running of the program at time t3. Moreover, the state change of voltage NRST at connection terminal 114 for example triggers the emission of the alert signal by circuit 13 so that rechargeable battery 102 is charged by the user.

In certain cases where comparator 112 exhibits a hysteresis, when the processor 118 of circuit 11 stops the running of the program, the current consumption of device 100 decreases and voltage VBAT increases back above VLIM but while remaining lower than the second limiting voltage of voltage comparator 112. Voltage NRST remains in the second state.

An advantage of the described embodiments is that a verification of the battery charge level can be performed without the addition of either a voltage comparator or of an analog-to-digital converter in the circuit 13 comprising non-volatile memory 132. Circuit 13 can thus remain relatively compact, which is particularly advantageous in the case where circuit 13 is a host circuit of a connected object.

Various embodiments and variants have been described. Those skilled in the art will understand that certain features of these various embodiments and variants may be combined, and other variants will occur to those skilled in the art. In particular, although an example comprising a voltage dividing bridge has been described, in other embodiments this dividing bridge is omitted, the voltage VBAT of battery 102 being for example directly compared with limiting voltage VLIM.

Further, although in FIG. 3 device 100 comprises a low-dropout voltage regulator 106, in other embodiments, other types of voltage regulator may be used, for example a switched-mode power supply (SMPS).

Finally, the practical implementation of the described embodiments and variants is within the abilities of those skilled in the art based on the functional indications given hereabove.

1. A device comprising:
a rechargeable battery;
a first circuit comprising a processor and a voltage comparator configured to compare a voltage of the rechargeable battery with a limiting voltage; and
a second circuit, coupled to the first circuit, comprising a memory of non-volatile type and configured to initialize the processor of the first circuit if the voltage of the rechargeable battery is higher than the limiting voltage.

2. The device of claim 1, wherein the memory of the second circuit is a flash-type memory.

3. The device of claim 1, further comprising a voltage regulator configured to supply the first and second circuits with voltage.

4. The device of claim 1, wherein the first circuit comprises a connection terminal coupled to a connection terminal of the second circuit, a signal present at the connection terminal of the first circuit being either in a first state or in a second state, according to a charge level of the rechargeable battery.

5. The device of claim 4, wherein the signal present at the connection terminal of the first circuit is in the second state if the voltage of the rechargeable battery is lower than the limiting voltage.

6. The device of claim 4, wherein the second circuit is configured to reset the processor or to generate an alert signal if the signal present at the connection terminal of the first circuit is in the second state.

7. The device of claim 4, wherein a voltage of the connection terminal of the first circuit in the first state is higher than the voltage of the connection terminal of the first circuit in the second state.

8. The device of claim 1, wherein the first circuit further comprises an analog-to-digital converter configured to generate a digital value representative of the voltage of the rechargeable battery.

9. The device of claim 1, wherein the rechargeable battery is a lithium battery.

10. A Method comprising:
comparing, by a first circuit, of a voltage of a rechargeable battery with a limiting voltage; and
initializing a processor of the first circuit, by a second circuit comprising a memory of non-volatile type, if the voltage of the rechargeable battery is higher than the limiting voltage.

11. The method of claim 10, also comprising, prior to the running of a program by the processor, the comparison of the voltage of the rechargeable battery with a threshold voltage, and the running of the program only if the voltage of the rechargeable battery is higher than the threshold voltage.

12. The method of claim 10, further comprising the resetting of the processor or a emission of an alert signal by the second circuit if the voltage of the rechargeable battery is lower than the limiting voltage.
